(19) United States
(12) Patent Application Publication
(10) Pub. No.: US 2001/0021593 A1
(43) Pub. Date: Sep. 13, 2001

(54) Chemical vapor deposition apparatus and chemical vapor deposition process

(75) Inventors: Shiro Sakai, Tokushima-ken (JP); Koichi Kitahara, Kanagawa-ken (JP); Yukichi Takamatsu, Kanagawa-ken (JP); Yuji Mori, Kanagawa-ken (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Japan Pionics Co., Ltd., Tokyo (JP)

(21) Appl. No.: 09/791,708

(22) Filed: Feb. 26, 2001

(30) Foreign Application Priority Data
Mar. 8, 2000 (JP) 62899/2000

(51) Int. Cl. H01L 21/31

(52) U.S. Cl. 438/784

(57) ABSTRACT

A chemical vapor deposition apparatus for forming a semiconductor film, which includes a lateral reaction tube including a susceptor for placing a substrate thereon; a round-shaped heater for heating the substrate; and a gas inlet for introducing a gas containing at least one source gas, the inlet being provided so as to be substantially parallel to the substrate, wherein the heating density of an upstream portion, with respect to the flow of the gas, of the round-shaped heater is higher than that of the remaining portion of the heater. A chemical vapor deposition process employing the chemical vapor deposition apparatus is also disclosed.

### BACKGROUND OF THE INVENTION

1. Field of the Invention

The present invention relates to a chemical vapor deposition apparatus and a chemical vapor deposition process for forming a semiconductor film, and more particularly to an apparatus and process for vapor-growth of a semiconductor film on a heated substrate by introducing a source gas through a gas inlet in the apparatus, the gas inlet being provided so as to be substantially parallel to the substrate.

2. Background Art

There are conventionally known chemical vapor deposition apparatuses in which a source gas is passed through a reaction tube while a substrate placed in the tube is heated to thereby form a thin film such as semiconductor crystal film on the substrate, and chemical vapor deposition processes carried out through use of such apparatuses. For example, there has been carried out a process in which a source gas, such as trimethylgallium, trimethylaluminum, or ammonia, and a dilution gas, such as hydrogen or nitrogen, are supplied through one or more gas inlets which are provided so as to be substantially parallel to a heated substrate, to thereby vapor-grow a crystal on the substrate.

In order to carry out such a process, for example, a reaction tube 1 for vapor-growth of a semiconductor film, which is shown in FIG. 1, is employed as a chemical vapor deposition apparatus. The reaction tube 1 includes a susceptor 3 for placing a substrate 2 thereon, a heater 4 for heating the substrate 2, a gas inlet 5, and a gas outlet 6. In the process, a gas containing a source gas is supplied through the gas inlet 5 while the substrate 2 is heated at a high temperature, to thereby deposit a semiconductor film on the substrate 2.

When the above process is carried out by use of such an apparatus, in accordance with use of a semiconductor film, sapphire, SiC, or bulk gallium nitride is employed as a substrate, and an organometallic compound, a metal hydride, ammonia, hydrazine, or an alkylamine is employed as a source gas. In accordance with the type of a semiconductor film, the substrate is heated in the vicinity of 600° C. or at 1,100-1,200° C.

When such a semiconductor film is vapor-grown, in order to form a film having a uniform thickness, a heater exhibiting uniform heating characteristic is employed, and a substrate is rotated on a susceptor. When a plurality of substrates are simultaneously heated, each substrate on the susceptor is rotated about its own center while moved along with the rotation of the susceptor.

In recent years, a nitride of a Group III element, such as indium, gallium, or aluminum, has been employed in practice for forming a blue-light semiconductor film. In accordance with this trend, there have been studied processes for effectively forming a semiconductor film exhibiting uniform characteristic in mass production. In order to vapor-grow such a Group III element nitride semiconductor film, the substrate must be heated to as high as about 1,150° C. When the heating temperature is higher or lower than the above temperature, defects occur in the crystal and the resultant semiconductor film fails to exhibit excellent characteristics. Therefore, the substrate must be heated uniformly at a temperature within a desired narrow range.

In the case in which vapor-growth is carried out at such a high temperature, when a gas containing a source gas is heated over a substrate, thermal convection occurs, and thus a reaction product or a decomposition product of the source gas is deposited on a wall of a reaction tube, which wall faces the substrate, and the wall is contaminated. In addition, when the deposited solid falls on the substrate, the quality of the formed crystal is considerably lowered. Therefore, the reaction tube must be cleaned every time vapor-growth is carried out, resulting in poor productivity.

In order to solve these problems, a variety of processes have been proposed. For example, there has been proposed a process in which a reaction tube wall facing a substrate, which wall may cause contamination, is removed; a gas injection tube is provided at a position perpendicular to the substrate; a gas containing a source gas is introduced through one or more passages provided at a position parallel to the substrate; and a gas containing no source gas is introduced through the gas injection tube, to thereby urge the gas containing the source gas onto the substrate (this process is a modification of the process disclosed in Japanese Patent No. 2628404). When this process is carried out, in the case in which two or more gasses containing the source gas are supplied through the passages provided so as to be parallel to the substrate, the gasses can be mixed together.

However, in this process, two gas flows crossing at an right angle with each other are mixed over the substrate, and thus the gas flows are disturbed. Consequently, switching of the gasses cannot be carried out instantaneously; the source gas is not effectively utilized, because of short pass; and the source gas cannot be supplied to the substrate at a uniform concentration over a large area.

Therefore, this process involves a problem in that it cannot be carried out in a large apparatus in which a large substrate is treated or a plurality of substrates are treated simultaneously.

Moreover, the aforementioned processes are problematic in that, in the case in which a plurality of substrates are employed simultaneously or a large-sized substrate is employed, when vapor-growth is carried out, the resultant semiconductor film exhibits poor characteristics as compared with a semiconductor film that has been vapor-grown on a small-sized substrate. In addition, a large amount of decomposition product of the source gas is deposited on a reaction tube wall, and the source gas is not effectively utilized.

### SUMMARY OF THE INVENTION

In view of the foregoing, an object of the present invention is to provide a chemical vapor deposition apparatus and a chemical vapor deposition process for treating a plurality of substrates simultaneously or a substrate having a large area by use of a lateral reaction tube, in which a semiconductor film exhibiting excellent characteristics is formed, a source gas is effectively utilized, and deposition of a decomposition product or a reaction product of the source gas on a wall of the reaction tube is prevented.

In order to solve the aforementioned problems, the present inventors have performed extensive studies, and have found that, when a chemical vapor deposition process is carried out by use of a chemical vapor deposition apparatus for forming a semiconductor film—the apparatus including a lateral reaction tube—the temperature of the upstream side (with respect to the flow of a gas containing a source gas) of a substrate which contacts the gas containing the source gas supplied through a gas inlet provided so as to be substantially parallel to the substrate, is slightly lowered; that the resultant semiconductor film exhibits poor characteristics; a large amount of deposition is found on the wall of the reaction tube; and the source gas is not effectively utilized. The present inventors have also found that, when the heating density of the upstream side (with respect to the flow of the gas containing the source gas) of a heater is increased as compared with that of the downstream side of the heater, a semiconductor film exhibiting excellent characteristics can be formed. The present inventors have also found that, when a gas containing no source gas is supplied through a gas-permeable microporous portion provided on a reaction tube wall facing the substrate, the amount of deposition on the wall can be considerably reduced. The present invention has been accomplished on the basis of these findings.

Accordingly, the present invention provides a chemical vapor deposition apparatus for forming a semiconductor film, which comprises a lateral reaction tube comprising a susceptor for placing a substrate thereon; a round-shaped heater for heating the substrate; and a gas inlet for introducing a gas containing at least one source gas, the inlet being provided so as to be substantially parallel to the substrate, wherein the heating density of an upstream portion, with respect to the flow of the gas, of the round-shaped heater is higher than that of the remaining portion of the heater.

The present invention also provides a chemical vapor deposition apparatus for forming a semiconductor film, which comprises a lateral reaction tube comprising a susceptor for placing a substrate thereon; a round-shaped heater for heating the substrate; a gas inlet for introducing a gas containing at least one source gas, the inlet being provided so as to be substantially parallel to the substrate; a gas-permeable microporous portion provided on a reaction tube wall facing the substrate so as to be parallel with the substrate; and a gas inlet for introducing a gas containing no source gas through the microporous portion, wherein the heating density of an upstream portion, with respect to the flow of the gas containing the source gas, of the round-shaped heater is higher than that of the remaining portion of the heater.

The present invention also provides a chemical vapor deposition process which comprises supplying a gas containing a source gas through a gas inlet which is provided so as to be substantially parallel to a substrate placed on a susceptor in a lateral reaction tube, while heating the substrate by use of a heater, to thereby vapor-grow a semiconductor film on the substrate, wherein the heating density of an upstream portion, with respect to the flow of the gas containing the source gas, of the heater is higher than that of the remaining portion of the heater.

The present invention also provides a chemical vapor deposition process which comprises supplying a gas containing a source gas through a gas inlet which is provided so as to be substantially parallel to a substrate placed on a susceptor in a lateral reaction tube, while heating the substrate by use of a heater; and introducing a gas containing no source gas into the reaction tube through a microporous portion provided on a reaction tube wall facing the substrate so as to be parallel with the substrate, to thereby vapor-grow a semiconductor film on the substrate, wherein the heating density of an upstream portion, with respect to the flow of the gas containing the source gas, of the heater is higher than that of the remaining portion of the heater.

The present invention also provides a chemical vapor deposition apparatus and a chemical vapor deposition process for vapor-growing a semiconductor film by supplying a gas containing a source gas onto a heated substrate in a lateral reaction tube, wherein the heating density of an upstream portion, with respect to the flow of the gas containing the source gas, of a heater is higher than that of the remaining portion of the heater, to thereby heat the substrate uniformly at a temperature within a desired narrow range, form an excellent semiconductor film, employ the source gas effectively, and reduce the amount of a decomposition product or a reaction product of the source gas, the product being deposited on the wall of the reaction tube.

The present invention also provides a chemical vapor deposition apparatus and a chemical vapor deposition process, wherein the heating density of an upstream portion, with respect to the flow of a gas containing a source gas, of a heater is higher than that of the remaining portion of the heater, and a gas containing no source gas is introduced into a reaction tube through a microporous portion provided on a reaction tube wall facing a substrate so as to be parallel with the substrate, to thereby considerably reduce the amount of a decomposition product or a reaction product of the source gas, the product being deposited on the wall.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with accompanying drawings, in which:

FIG. 1 is a longitudinal sectional view showing a chemical vapor deposition apparatus (including a microporous portion) of the present invention;

FIG. 2 is a plan view showing an example susceptor (for six substrates) included in the chemical vapor deposition apparatus of the present invention;

FIG. 3 is a plan view showing an example heater (1) included in the chemical vapor deposition apparatus of the present invention; and

FIG. 4 is a plan view showing an example heater (2) included in the chemical vapor deposition apparatus of the present invention.

### DETAILED DESCRIPTION OF PREFERRED EMBODIMENTS

The present invention is applicable to a chemical vapor deposition apparatus and a chemical vapor deposition process for forming a semiconductor film.

The present invention is applicable to production of a Group III metal phosphide semiconductor film or a Group III metal arsenide semiconductor film. Preferably, the present invention is applied to a chemical vapor deposition apparatus and a chemical vapor deposition process for producing a Group III metal nitride semiconductor film at a temperature higher than 1,000° C.

The chemical vapor deposition apparatus of the present invention will be described with reference to FIG. 1. The chemical vapor deposition apparatus of the present invention includes a lateral reaction tube 1. The reaction tube 1 includes a substrate 2; a susceptor 3 for placing the substrate thereon and rotating the substrate; a heater 4 for heating the substrate; a gas inlet 5 provided so as to be substantially parallel to the substrate; and a gas outlet 6. If desired, the reaction tube 1 includes a gas-permeable microporous portion 7 provided on a reaction tube wall facing the substrate so as to be parallel with the substrate, and a gas inlet 8 for introducing a gas containing no source gas.

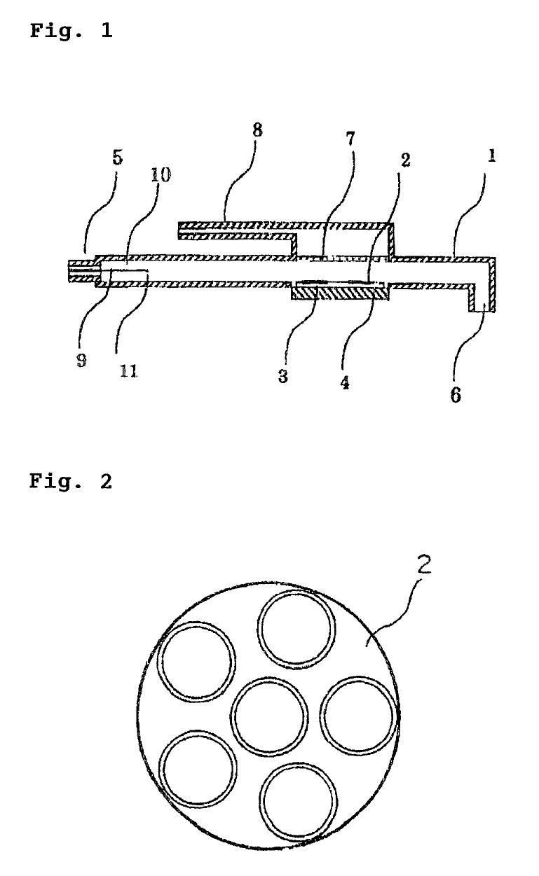

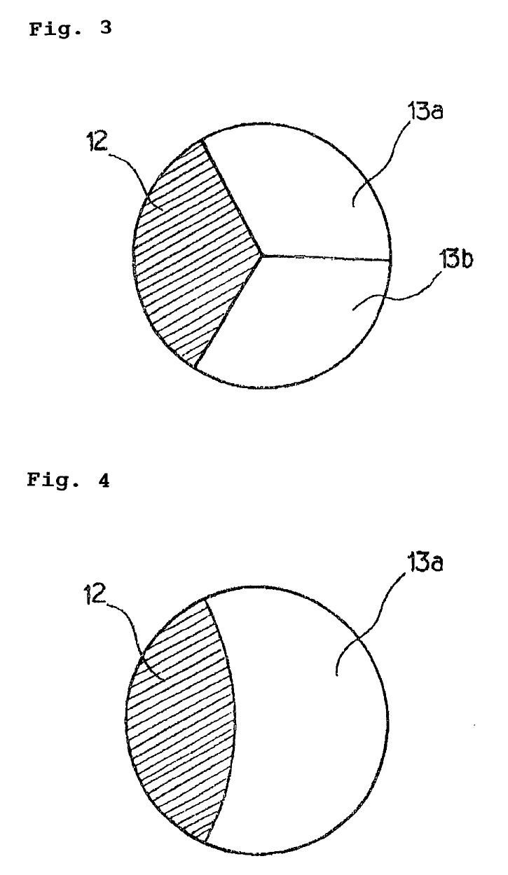

FIG. 2 shows a plan view of an example susceptor 3 (for six substrates); and FIG. 3 shows a plan view of an example heater 4. The heater 4 shown in FIG. 3 includes three radially-divided fan-shaped sections; i.e., heater sections 12, 13a, and 13b, each having a central angle of 120°.

In the present invention, the heating density of the upstream portion, with respect to the flow of a gas containing a source gas, of the heater; i.e., the heater section 12, is higher than that of the remaining portion (including the downstream portion) of the heater; i.e., the heater sections 13a and 13b.

In the present invention, the cross-section of the reaction tube, particularly at a position at which vapor-growth is carried out, may assume a round shape or an oblong oval shape. Preferably, the cross-section of the reaction tube assumes an oblong rectangular shape in which distance between the substrate and the reaction tube wall facing the substrate is short.

The gas inlet 5 may be a single gas inlet. A partition 9 may be provided so as to divide the gas inlet into two parts; i.e., a first passage 10 and a second passage 11, so that each source gas can be supplied through one passage. Furthermore, addition of a second partition may provide a third passage.

As described above, in the chemical vapor deposition apparatus of the present invention, no particular limitations are imposed on the cross-sectional shape of the reaction tube, the shape of the gas inlet, and the system of the gas inlet.

In the present invention, the heater 4 includes the sections 12, 13a, and 13b, in which the heating density of the upstream portion (with respect to the flow of a gas containing a source gas supplied through the gas inlet which is provided so as to be substantially parallel to the substrate) of the heater (the heater section 12) is higher than that of the remaining portion of the heater (the heater sections 13a and 13b).

The heater is constituted of electrical resistors made of, for example, molybdenum, tungsten, silicon carbide, and thermally decomposed graphite. Usually such a material is employed as is, or is coated with an insulating material such as boron nitride. No limitation is imposed on the type of the resistor, coating of the resistor with an insulating material, and the type of the insulating material.

In the present invention, the heater is usually formed of a material having a disk shape which is similar to that of the susceptor. The upstream heater section is, as shown in FIG. 3, a fan-shaped section exhibiting symmetry with respect to the center axis of the lateral reaction tube, such that either edge line of the fan-shaped section and the center axis forms an angle of ±(40 to 9)°, preferably ±(50 to 75)°. The heating density of the upstream heater section is higher than that of the remaining section.

The heater may consist of the fan-shaped sections having the central angle as shown in FIG. 3. However, as shown in FIG. 4, the heater may be a round-shaped heater including a convex-lens-shaped section as an integration type on the upstream portion, at which the heating density differs from the remaining portions of the heater. In the present invention, in order to facilitate assembly of the heater and maintenance thereof, the heater preferably consists of divided sections shown in FIG. 3. The heating density of the round-shaped heater may be gradually changed along the circumference, to thereby impart uniform distribution of the temperature of the substrate during vapor-growth.

In the present invention, no particular limitation is imposed on the ratio of the heating density (w/cm²) of the upstream portion of the heater to that of the remaining portion thereof, so long as the heating density of the upstream portion is higher than that of the remaining portion. The ratio is usually 1.1-2.0:1, preferably 1.2-1.8:1. The method for producing difference in heating density between these two portions is not particularly limited. In order to produce such difference, the heater may be formed from different resistors; the heater may be formed so that the resistors do not exhibit uniform distribution; or voltage applied to the resistor may be changed or the waveform of the voltage may be changed.

The heating density (w/cm²) of any section of the heater is not particularly determined, since the density varies in accordance with the heating temperature of the substrate, the flow rate of the source gas, the flow rate of the carrier gas, and the shape and size of the reaction tube. Usually, the heating density falls within a range of about 25-100 (w/cm²).

In the present invention, a known technique may be applied to the susceptor. One or more substrates are placed on the susceptor, and in accordance with the number of substrates held by the susceptor, each of the substrates may be rotated about its own center or moved as the susceptor is rotated, to thereby carry out vapor-growth uniformly. No particular limitation is imposed on the structure and shape of the susceptor, so long as the susceptor efficiently transmits heat from the heater to the substrate.

No particular limitation is imposed on means for transmitting heat between the heater and the substrate(s). In order to prevent contamination of the substrate(s) and to transmit heat uniformly between the heater and the substrate(s), quartz and/or a plate made from carbon may be provided therebetween.

No particular limitation is imposed on the substrate employed in the present invention, and sapphire, SiC, or bulk gallium nitride may be employed. The size and number of the substrates placed on the susceptor are not particularly limited.

In the chemical vapor deposition apparatus of the present invention, the distance between the substrate and the reaction tube wall facing the substrate is usually 20 mm or less, preferably 10 mm or less, more preferably 5 mm or less. When the distance is maintained within the above range, efficiency in employment of the source gas can be enhanced.

In the present invention, in order to prevent deposition of a decomposition product or a reaction product of the source gas onto the reaction tube wall facing the substrate during vapor-growth, a gas-permeable microporous portion may be provided on the reaction tube wall facing the substrate so as to be parallel with the substrate, to thereby introduce a gas containing no source gas through numerous micropores of the portion. Through the introduction of the gas, the gas containing no source gas forms a thin gas layer on the reaction tube wall facing the substrate, and thus prevents deposition of a decomposition product or a reaction product of the source gas onto the reaction tube wall. As a result, efficiency in employment of the source gas can be enhanced.

The microporous portion may be formed of numerous straight micropipes, but is preferably formed of a sintered body of vitreous silica, since such a sintered body enables formation of a thin gas layer on the reaction tube wall.

The pore size of the sintered body is not particularly limited. However, when the pore size is large, gas may fail to flow uniformly through the microporous portion, whereas when the pore size is very small, loss of pressure increases and the flow rate of gas becomes unsatisfactory. Therefore, the pore size is usually about 0.1-3 mm, preferably 0.3-2 mm.

In the chemical vapor deposition apparatus, the size of the microporous portion is not determined unconditionally, since the size varies in accordance with the shape of the reaction tube and the method for introducing the gas containing no source gas into the reaction tube. The microporous portion is provided at a position on the reaction tube wall facing the substrate, which position is slightly shifted upstream with respect to the region of the wall correspondingly facing the substrate. Alternatively, the microporous portion is provided in the vicinity of the above position. The size of the microporous portion may correspond to that of the substrate. However, when the microporous portion is provided so as to extend downstream with respect to the substrate, contamination of the reaction tube on the downstream side can be prevented. The size of the microporous portion is usually 0.5-5 times that of the substrate, preferably about 1.0-3.5 times. As used herein, the term “the size of the substrate” refers to the area of the region enclosed by the outermost trace which is formed by the end of the substrate during vapor-growth. Therefore, the size of the substrate is usually approximately equal to the area of the region enclosed by the circumference of the susceptor.

In the chemical vapor deposition apparatus of the present invention, as shown in FIG. 1, the gas inlet for supplying the gas containing no source gas through the gas-permeable microporous portion provided on the reaction tube wall may be provided at the position at which the microporous portion is provided. Alternatively, the gas inlet may be integrated with a reaction tube through modification of the tube wall so as to have a double-wall structure. In addition, the microporous portion may have a curved shape in order to enhance pressure-resistance and thermal strength of the portion.

In the chemical vapor deposition process of the present invention, vapor-growth is carried out under conditions such that, as described above, the heating density of the upstream portion—with respect to the flow of the gas containing the source gas—of the heater is higher than that of the remaining portion of the heater.

No particular limitation is imposed on the substrate employed in the present invention, and sapphire, SiC, or bulk gallium nitride may be employed. The number of substrates which are treated simultaneously is not particularly limited.

In the chemical vapor deposition process of the present invention, various source gasses are employed for vapor-growth, in accordance with the intended semiconductor film. Examples of such source gasses include metal hydrides such as arsine, phosphine, and silane; organometallic compounds such as trimethylgallium, trimethylindium, and trimethylaluminum; ammonia; hydrazine; and alkylamines. As used herein, the term “source gas” refers to a gas serving as a source of an element which is contained in crystal as an element constituting the crystal during growth of the crystal. The source gas is diluted with hydrogen, helium, argon, or nitrogen, and the resultant gas mixture may be employed as a gas containing the source gas.

In the chemical vapor deposition process of the present invention, a gas containing no source gas, which is introduced through the gas-permeable microporous portion into the reaction tube, is employed for forming a thin gas layer on the reaction tube wall, and thus does not contribute to vapor-growth. Usually, hydrogen, helium, argon, or nitrogen is employed. Since such a gas is employed for forming a thin gas layer, the flow rate of the gas—per area of the microporous portion, the area being equal to that of the substrate—is usually about ⅕-1/30, preferably about ⅕-1/10, that of the gas containing the source gas. When the flow rate is higher than the above value, disturbance of gas may occur over the substrate, whereas when the flow rate is very low, a thin gas layer is not formed, and thus the effect of supply of the gas containing no source gas is not obtained.

The phrase “per area of the microporous portion, the area being equal to that of the substrate” is used in the above description. Therefore, when the microporous portion is provided so as to extend downstream with respect to the region of the reaction tube wall facing the substrate, the flow rate of the gas containing no source gas increases in correspondence with the extended area of the microporous portion.

In the present invention, as described above, the gas containing no source gas, which is introduced through the gas-permeable microporous portion, is usually a gas which does not contribute to vapor-growth. However, for example, ammonia, the decomposition product of which assumes gaseous form, may be employed as the gas containing no source gas, instead of hydrogen, helium, or nitrogen. Alternatively, ammonia may be employed in combination with hydrogen, helium, or nitrogen.

By use of the reaction tube described above, vapor-growth can be carried out without causing contamination of the reaction tube wall facing the substrate. In addition, a deposition product or a reaction product of the source gas does not fall from the reaction tube wall, and vapor-growth processes can be repeatedly carried out without cleaning of the reaction tube.

According to the chemical vapor deposition process and the chemical vapor deposition apparatus of the present invention, when vapor-growth is carried out at 1,000° C. or higher, the temperature of a substrate is maintained consistent, and thus a semiconductor film exhibiting excellent characteristics can be vapor-grown. In addition, contamination of a reaction tube wall facing the substrate so as to be parallel with the substrate, which contamination is caused by deposition of a decomposition product or a reaction product of a source gas, can be prevented, and thus efficiency in employment of the source gas can be enhanced. Furthermore, vapor-growth processes can be carried out repeated without cleaning of the reaction tube. In addition, a crystal of high quality is reliably obtained at high yield, since falling of a solid product onto the substrate is prevented.

The present invention will next be described in more detail by way of embodiments, which should not be construed as limiting the invention thereto.

### EXAMPLE 1

There was produced a chemical vapor deposition apparatus including a reaction tube made of quartz, the tube having a structure similar to that shown in FIG. 1 and having inner dimensions (width: 280 mm, height: 20 mm, length: 1,500 mm), such that six substrates, each having a diameter of 2 inches, can be treated simultaneously.

Around-shaped heater (diameter: 260 mm) was formed of thermally-decomposed graphite insulation-coated with boron nitride. The heater was divided into three fan-shaped sections, each section having a central angle of 120°. The ratio of the heating density of an upstream portion (with respect to the flow of a gas containing a source gas) of the heater to that of the remaining portion of the heater was determined to be 1.3:1. The area of a gas-permeable microporous portion, the portion being provided on a reaction tube wall facing a substrate so as to be parallel with the substrate, was 1.5 times that of a susceptor.

By use of this apparatus, as described below, GaN crystal was vapor-grown on sapphire substrates having a diameter of 2 inches.

Each of the sapphire substrates was placed on the susceptor, and gas in the reaction tube was replaced by hydrogen gas. Subsequently, while a gas mixture of ammonia and hydrogen (ammonia: 40 L/min., hydrogen: 10 L/min.) was introduced through a first passage of a gas inlet, and nitrogen gas (50 L/min.) was supplied through the microporous portion, the temperature of the substrate was heated at 1,050° C. for 20 minutes, to thereby carry out heat-treatment of the substrate. After the temperature of the substrate was elevated to and maintained at 1,150° C., while the gas mixture of ammonia and hydrogen (ammonia: 40 L/min., hydrogen: 10 L/min.) was introduced through the first passage of the gas inlet, hydrogen gas containing trimethylgallium (trimethylgallium: 240 μmol/min., hydrogen: 50 L/min.) was introduced through a second passage of the gas inlet. Simultaneously, nitrogen gas (50 L/min.) was supplied through the microporous portion, to thereby carry out vapor-growth of GaN for 60 minutes. During vapor-growth of GaN, the susceptor was rotated at 12 rpm. Vapor-growth was carried out five times through the above procedure.

As used herein, the term “L/min.” refers to liters/minute

During vapor-growth, deposition of a solid product onto the reaction tube wall facing the substrate was not observed. After cooling of the substrate, the substrate was removed from the reaction tube, and the thickness of the GaN film was measured. As a result, the average thickness was found to be 2±0.1 μm, and the thickness was found to be uniform.

Electric characteristics of the thus-formed GaN films were measured, and the average carrier concentration and the average carrier mobility were found to be 3×10¹⁷/cm³ and 450 cm²/V.s, respectively. The results reveal that crystal exhibiting excellent characteristics was obtained.

### EXAMPLE 2

The procedure of Example 1 was repeated, except that the heater was replaced by a heater of the integration type (diameter: 260 mm) formed of thermally-decomposed graphite insulation-coated with boron nitride; and that the ratio of the heating density of a convex lens-shaped portion as shown in FIG. 4 to that of the remaining portion was determined to be 1.35:1, which convex lens-shaped portion is enclosed the circumference of the heater and a trace of a circle having a diameter of 500 mm, the center of the circle being 500 mm distant from the center of the heater. Through the procedure, GaN crystal was grown on sapphire substrates having a diameter of 2 inches.

During vapor-growth, deposition of a solid product onto the reaction tube wall facing the substrate was not observed. After cooling of the substrate, the substrate was removed from the reaction tube, and the thickness of the GaN film was measured. The average thickness was found to be 2.1±0.1 μm, and the thickness was found to be uniform.

Electric characteristics of the thus-formed GaN films were measured, and the average carrier concentration and the average carrier mobility were found to be 3×10¹⁷/cm³ and 420 cm²/V.s, respectively. The results reveal that crystal exhibiting excellent characteristics was obtained.

### Comparative Example 1

The procedure of Example 1 was repeated, except that the heating density of the heater, which was evenly divided into 120° fan-shaped sections, was determined to be uniform; the reaction tube was replaced by a reaction tube containing no microporous portion; and correspondingly, nitrogen was not introduced through the reaction tube wall facing the substrate so as to be parallel with the substrate, to thereby carry out vapor-growth of GaN.

Consequently, during vapor-growth, a solid product was observed to be deposited gradually from a region of the reaction tube wall facing the substrate toward the downstream direction. When vapor-growth was carried out twice, falling of the deposition on the reaction tube wall onto the substrate was observed. As a result, characteristics of the substrate surface were considerably impaired.

After vapor-growth was carried out once, the thickness of the GaN film was measured. As a result, the average thickness was found to be 2.1±0.1 μm. Electric characteristics of the thus-formed GaN film were measured, and the carrier concentration and the carrier mobility were found to be 1.5×10¹⁸/cm³ and 320 cm²/V.s, respectively.

What is claimed is:

1. A chemical vapor deposition apparatus for forming a semiconductor film, which comprises a lateral reaction tube comprising a susceptor for placing a substrate thereon; a round-shaped heater for heating the substrate; and a gas inlet for introducing a gas containing at least one source gas, the inlet being provided so as to be substantially parallel to the substrate, wherein the heating density of an upstream portion, with respect to the flow of the gas, of the round-shaped heater is higher than that of the remaining portion of the heater.

2. A chemical vapor deposition apparatus for forming a semiconductor film, which comprises a lateral reaction tube comprising a susceptor for placing a substrate thereon; a round-shaped heater for heating the substrate; a gas inlet for introducing a gas containing at least one source gas, the inlet being provided so as to be substantially parallel to the substrate; a gas-permeable microporous portion provided on a reaction tube wall facing the substrate so as to be parallel the substrate; and a gas inlet for introducing a gas containing no source gas through the microporous portion, wherein the heating density of an upstream portion, with respect to the flow of the gas containing the source gas, of the round-shaped heater is higher than that of the remaining portion of the heater.

3. A chemical vapor deposition apparatus according to claim 1, wherein the ratio of the heating density of the upstream portion of the round-shaped heater to that of the remaining portion of the heater is 1.1-2:1.

4. A chemical vapor deposition apparatus according to claim 2, wherein the ratio of the heating density of the upstream portion of the round-shaped heater to that of the remaining portion of the heater is 1.1-2:1.

5. A chemical vapor deposition apparatus according to claim 1, wherein the upstream portion of the round-shaped heater is a fan-shaped portion, such that either edge line of the fan-shaped portion and the line corresponding to the center axis of the lateral reaction tube forms an angle of ±(40 to 90)°.

6. A chemical vapor deposition apparatus according to claim 2, wherein the upstream portion of the round-shaped heater is a fan-shaped portion, such that either edge line of the fan-shaped portion and the line corresponding to the center axis of the lateral reaction tube forms an angle of ±(40 to 90)°.

7. A chemical vapor deposition process which comprises supplying a gas containing a source gas through a gas inlet which is provided so as to be substantially parallel to a substrate placed on a susceptor in a lateral reaction tube, while heating the substrate by use of a heater, to thereby vapor-grow a semiconductor film on the substrate, wherein the heating density of an upstream portion, with respect to the flow of the gas containing the source gas, of the heater is higher than that of the remaining portion of the heater.

8. A chemical vapor deposition process which comprises supplying a gas containing a source gas through a gas inlet which is provided so as to be substantially parallel to a substrate placed on a susceptor in a lateral reaction tube, while heating the substrate by use of a heater; and introducing a gas containing no source gas into the reaction tube through a microporous portion provided on a reaction tube wall facing the substrate so as to be parallel the substrate, to thereby vapor-grow a semiconductor film on the substrate, wherein the heating density of an upstream portion, with respect to the flow of the gas containing the source gas, of the heater is higher than that of the remaining portion of the heater.

9. A chemical vapor deposition process according to claim 7, wherein the ratio of the heating density of the upstream portion of the round-shaped heater to that of the remaining portion of the heater is 1.1-2:1.

10. A chemical vapor deposition process according to claim 8, wherein the ratio of the heating density of the upstream portion of the round-shaped heater to that of the remaining portion of the heater is 1.1-2:1.

11. A chemical vapor deposition process according to claim 7, wherein the upstream portion of the round-shaped heater is a fan-shaped portion, such that either edge line of the fan-shaped portion and the line corresponding to the center axis of the lateral reaction tube forms an angle of ±(40 to 90)°.

12. A chemical vapor deposition process according to claim 8, wherein the upstream portion of the round-shaped heater is a fan-shaped portion, such that either edge line of the fan-shaped portion and the line corresponding to the center axis of the lateral reaction tube forms an angle of ±(40 to 90)°.
